(19) United States
(12) Patent Application Publication
(10) Pub. No.: US 2009/0058541 A1
(43) Pub. Date: Mar. 5, 2009

(54) High-frequency ring coupled Quad

(76) Inventors: Zuo-Min Tsai, Taipei (TW); Huei Wang, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/071,934

(22) Filed: Feb. 28, 2008

(30) Foreign Application Priority Data
Aug. 31, 2007 (TW) 096132387

(51) Int. Cl. H03K 3/03

(52) U.S. Cl. 331/57

(57) ABSTRACT

The present invention discloses a high-frequency ring coupled Quad comprising at least two transistors, which are cascaded to form a ring and bonded to resonators to form an oscillation source. The open loop feedback gain of the ring coupler of the present invention is higher than that of a conventional cross-coupled pair oscillator because the present invention adopts at least two cascaded transistors. The present invention can solve the problems of low transistor gain and high substrate loss occurring at a high frequency. The present invention has a fully symmetric circuit topology and is free of additional interconnections lines, which can obviously reduce the stray effect of interconnection lines.

### BACKGROUND OF THE INVENTION

1. Field of the Invention

The present invention relates to a voltage controlled oscillator, particularly to a ring coupler fabricated with a 90-nm CMOS process.

2. Description of the Related Art

Oscillators are key components for wireless communication systems. A ring-coupled oscillator is often used at lower oscillation, wherein the lag time of transistors is used to control the oscillation frequency. However, the abovementioned circuit cannot operate at high oscillation frequency. Therefore, microwave or millimeter-wave applications do not use ring-coupled oscillators usually.

A cross-coupled pair has a negative real part of input admittance within a very wide frequency band; therefore, it is usually used to form an oscillator, called a “cross-coupled oscillator”, as shown in FIG. 1. In documents, the architecture of the traditional cross-coupled oscillator has been used in an oscillator with a fundamental frequency of 57 Hz and a second harmonic frequency of 114 Hz.

However, when a high-frequency cross-coupled oscillator performs a high fundamental operation frequency, such as W-band, it will meet the stray effect of interconnection lines, and the problems of low transistor gain and high substrate loss. There is also a high-frequency cross-coupled oscillator, which integrates transistors with cross-coupling interconnection lines in a special transistor topology. However, such a special topology needs a new circuit model for transistors, which will reduce design flexibility.

There is also an oscillator using a circular-geometry oscillator topology, wherein four cross-coupled pairs use common resonators. However, such a circuit design still cannot solve the stray effect of cross-coupling interconnection lines.

Therefore, the present invention proposes a high-frequency ring coupled Quad to solve the abovementioned problems.

### SUMMARY OF THE INVENTION

The primary objective of the present invention is to provide a high-frequency ring coupled Quad to solve the stray effect of cross-coupling between interconnection lines and the problems of low transistor gain and high substrate loss.

Another objective of the present invention is to provide a high-frequency ring coupled Quad to overcome the problems which a traditional ring coupler will meet when operating at a high frequency and to make the design of a high-frequency oscillator simpler and more flexible.

Still another objective of the present invention is to provide a high-frequency ring coupled Quad whose open loop feedback gain is greater than that of a conventional cross-coupled pair oscillator, and whereby the low transistor gain and high substrate loss occurring at a high frequency can be solved.

Further another objective of the present invention is to provide a high-frequency ring coupled Quad, wherein the topology thereof is fully symmetric without additional interconnection lines, and whereby the stray effect of interconnection lines is thus obviously reduced.

The present invention proposes a high-frequency ring coupled Quad, which comprises at least two transistors, wherein the transistors are ring-coupled via cascading, and wherein the transistors are bonded to resonators at the outer sides thereof to form an oscillation source.

As the ring coupler of the present invention comprises at least two cascaded transistors, the open loop feedback gain of the present invention is greater than that of a conventional cross-coupled pair oscillator. The present invention can overcome the problems of low transistor gain and high substrate loss occurring at a high frequency. Further, as the present invention has a fully symmetric topology and is free of additional interconnection lines, the present invention can obviously reduce the stray effect of interconnection lines.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1 is a diagram schematically showing the architecture of a conventional cross-coupled oscillator;

FIG. 2 is a diagram schematically showing the architecture of a high-frequency ring coupled Quad according to the present invention;

FIG. 3 is a diagram schematically showing the circuit topology of a high-frequency ring coupled Quad according to the present invention;

FIG. 4 is a diagram schematically showing the circuit of a ring quad-coupled oscillator according to the present invention; and

FIG. 5 is a diagram showing the results of the tests performed in the circuit of FIG. 4.

### DETAILED DESCRIPTION OF THE INVENTION

The ring coupler of the present invention can apply to realize a high-frequency (such as the W band) VCO (Voltage Controlled Oscillator). The ring coupler of the present invention comprises: at least two transistors and at least two resonators, wherein the transistors are cascaded to form a ring, and wherein the transistors are bonded to resonators at the outer sides thereof to form an oscillation source.

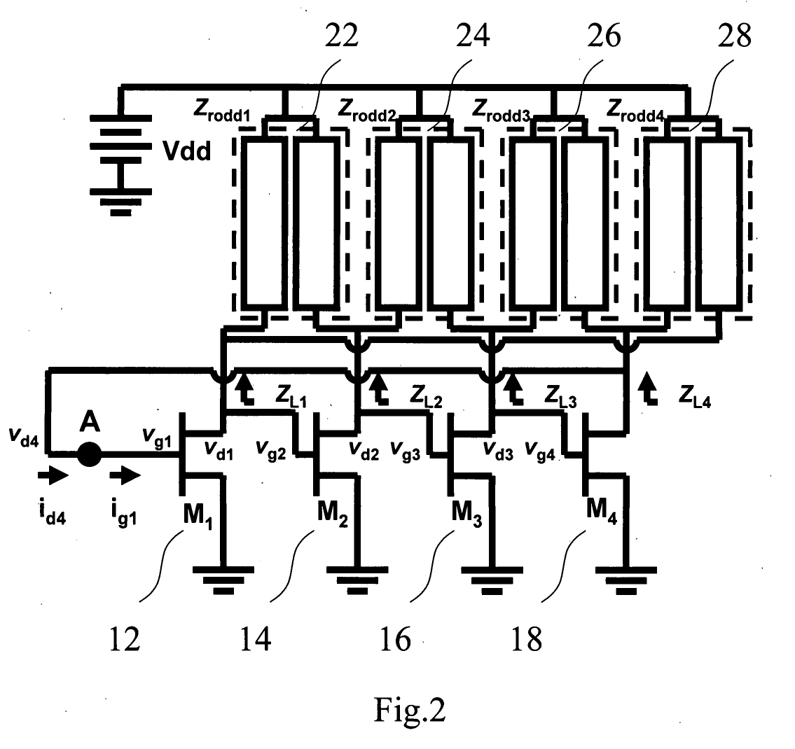

Below, an embodiment that the ring coupler comprises four transistors is used to exemplify the present invention. Refer to FIG. 2, wherein M₁, M₂, M₃, and M₄ respectively denote a first transistor 12, a second transistor 14, a third transistor 16 and a fourth transistor 18, and wherein Zrodd1, Zrodd2, Zrodd3, and Zrodd4 respectively denote a first resonator 22, a second resonator 24, a third resonator 26 and a fourth resonator 28. The abovementioned transistors are cascaded to form a ring, and the resonators are arranged outside the transistors. The ring coupler forms the negative conductance of broadband and cooperates with the resonators to form a ring quad-coupled oscillator circuit.

This embodiment utilizes the abovementioned four transistors to from a high-frequency ring coupled Quad, wherein the gate of one transistor is coupled to a drain of another transistor to form a four-stage amplifier, and wherein the input terminal is coupled to the output terminal. As shown in FIG. 2, the sources of the first, second, third and fourth transistors 12, 14, 16, and 18 are coupled to the ground. The drain of the first transistor 12 is coupled to the gate of the second transistor 14, the first resonator 22 and the forth resonator 28. The drain of the second transistor 14 is coupled to the gate of the third transistor 16, the second resonator 24 and the first resonator 22. The drain of the third transistor 16 is coupled to the gate of the fourth transistor 18, the third resonator 26 and the second resonator 24. The drain of the fourth transistor 18 is coupled to the gate of the first transistor 12, the fourth resonator 28 and the third resonator 26.

This embodiment is a quad ring coupler, wherein four transistors are cascaded to form a ring. In cooperation with the four resonators, each pair of neighboring transistors has a phase difference of 180 degrees. Thus, the combination of four cascaded transistors totally has a phase difference of 720 degrees, which amounts to the open loop feedback gain of a four-stage amplifier. The conventional cross-coupled pair uses only two transistors with the input and the output coupled to each other and has a phase difference of 360 degrees, and the open loop feedback gain thereof amounts to the gain of a two-stage amplifier.

Below, equations are used to calculate the open loop voltage gains of the present invention and the conventional technology. Open the loop from Point A in FIG. 2, and the open loop voltage gain of the present invention can be expressed by

ν_{d4}/ν_{g1}=(−gₘ₁Z_{L1}(ω))(−gₘ₂Z_{L2}(ω))(−gₘ₃Z_{L3}(ω))(−gₘ₄Z_{L4}(ω)) (Equation 1)

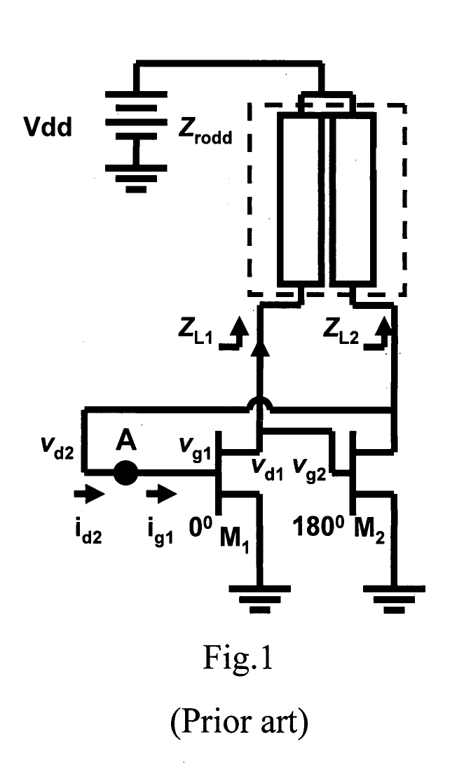

The conventional cross-coupled oscillator shown in FIG. 1 uses two transistors and is equivalent to a two-stage amplifier, wherein the gate of one transistor is coupled to the drain of the other transistor with the input and the output coupled to each other. Open the loop from Point A in FIG. 1, and the open loop voltage gain of the conventional technology can be expressed by

ν_{d2}/ν_{g1}=(−Z_{L1}(ω)gₘ₁)(−Z_{L2}(ω)gₘ₂) (Equation 2)

Suppose that the conductances of the transistors are identical, and that substrate losses are identical. It is known from Equation 1 and Equation 2 that the open loop voltage gain of the high-frequency ring coupled Quad of this embodiment is the square of that of the conventional cross-coupled oscillator. Therefore, the present invention can have higher transistor gain and lower substrate loss at a high frequency. For the design of a high-frequency oscillator, the feature of the present invention—increased open loop voltage gain—benefits design flexibility.

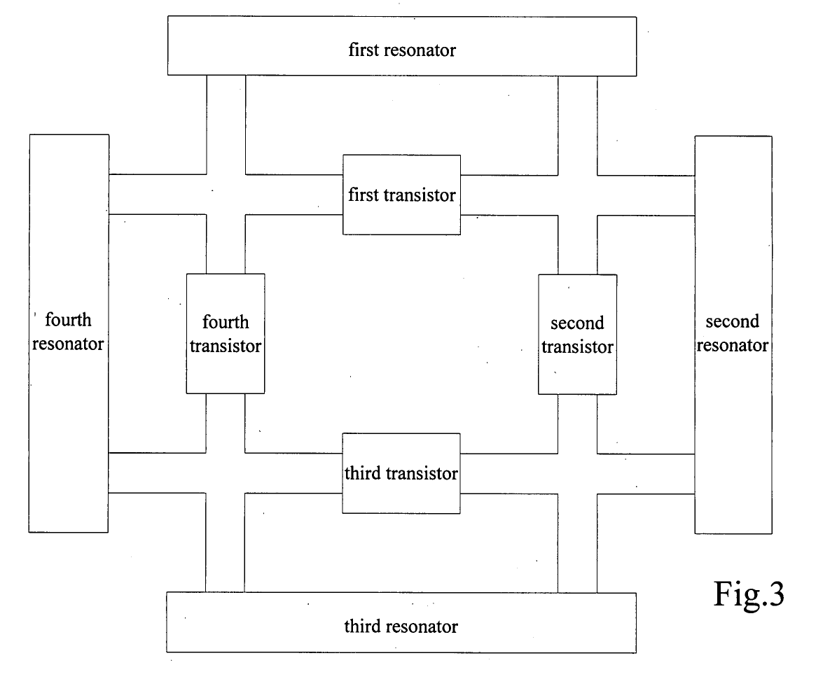

Another feature of the present invention is the symmetric circuit topology thereof. In comparison with the conventional cross-coupled pair oscillator needing additional interconnection lines, the high-frequency ring coupled Quad of the present invention has a fully symmetric circuit topology and is free of additional interconnection lines. Refer to FIG. 3. The fact that the beginning and end of the combination of the abovementioned four transistors are joined together, and the fact that the first resonator 22, second resonator 24, third resonator 26 and fourth resonator 28 are arranged to respectively face four sides, are exactly enough to form a ring quad-coupled oscillator without using any interconnection line. Therefore, compared with the conventional cross-coupled oscillator, the present invention can reduce the stray effect of interconnection lines.

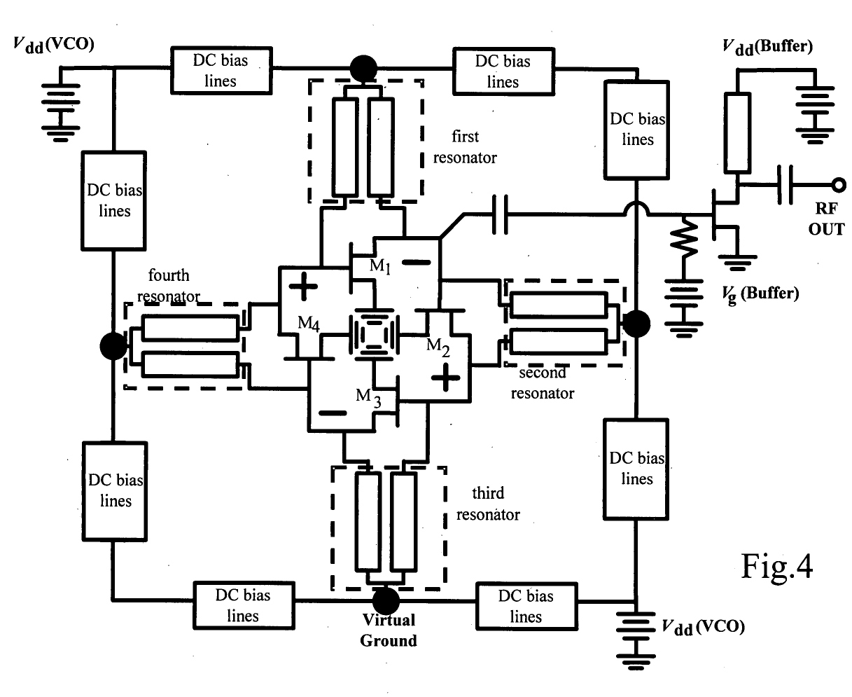

Refer to FIG. 4, wherein the first transistor 12, second transistor 14, third transistor 16 and fourth transistor 18 ring-coupled at the center together with the first resonator 22, second resonator 24, third resonator 26 and fourth resonator 28 respectively arranged in four sides form a high-frequency ring coupled Quad. The input voltage (V_{dd}(VCO)) of the voltage controlled oscillator is received from the ground via a direct-current power cable. The VCO (Voltage Controlled Oscillator) can be fabricated with a 90 nm CMOS (Complementary Metal Oxide Semiconductor) process. The VCO frequency can be tuned via adjusting the input voltage (V_{dd}(VCO)), and the VOC may have an oscillation frequency of 2.5 GHz. A capacitor couples node voltage to the input terminal of a buffer amplifier to form oscillation signals.

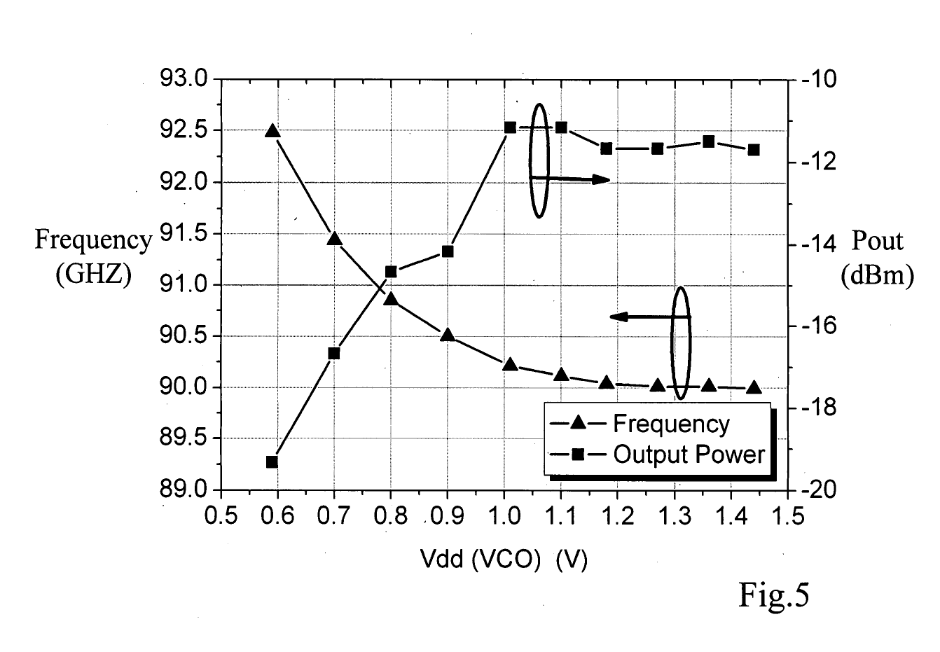

In the present invention, the gate and drain of each transistor are respectively connected to the terminals of one resonator, and the four transistors are cascaded to form a ring. As gate voltage is different from drain voltage in one device, the terminals of one resonator will have a virtual short circuit. DC bias lines are connected to the terminals of the resonators and will not influence the RF performance of the VCO. The output voltage is sampled via a 0.05 pF capacitor of the drain of the first transistor. The sampled voltage is amplified by a source buffer amplifier. The frequency is tuned via adjusting the input voltage (V_{dd}(VCO)) of the VCO to fix the bias condition of the buffer amplifier. The 0.05 pF capacitor locks the DC level of the input voltage V_{dd} of the VCO and the gate voltage of the buffer amplifier. The input voltage V_{dd} of the VCO and the input voltage V_{dd} of the buffer amplifier are separately supplied. FIG. 5 shows the results of the tests performed in the circuit of FIG. 4. There is over −20 dBm power output within the oscillation frequency range of 90-92.5 GHz, which proves the practicability of the present invention.

Besides, the present invention can overcome the problem of high loss, which makes a CMOS element hard to realize a fundamental oscillator at a high frequency. Therefore, the present invention meets the trend of the persistently increasing frequency in microwave application and the continuously progress of CMOS processes and can applies the voltage controlled oscillator fabricated with a CMOS process to a local oscillator of a communication system to improve system integration and reduce cost.

Those described above are only the preferred embodiments to exemplify the present invention but not to limit the scope of the present invention. Any equivalent modification or variation according to the shapes, structures, characteristics or spirit disclosed in the present invention is to be also included within the scope of the present invention.

What is claimed is:

1. A high-frequency ring coupled Quad comprising:
at least two transistors cascaded to form a ring; and
at least two resonators arranged in outer sides of said ring of said transistors with each said transistor bonded to said resonators to form an oscillation source.

2. A high-frequency ring coupled Quad according to claim 1, which comprises four transistors and four resonators, including:
a first transistor with a source thereof connected to a ground;
a second transistor with a gate thereof connected to a drain of said first transistor and a source thereof connected to a ground;
a third transistor with a gate thereof connected to a drain of said second transistor and a source thereof connected to a ground;
a fourth transistor with a gate thereof connected to a drain of said third transistor and a gate of said first transistor connected to a drain thereof and a source thereof connected to a ground, wherein said transistors are cascaded to form a ring;
a first resonator with one terminal thereof connected to said drain of said first transistor and said gate of said second transistor;
a second resonator with one terminal thereof connected to said drain of said second transistor, said gate of said third transistor and another terminal of said first resonator;
a third resonator with one terminal thereof connected to said drain of said third transistor, said gate of said fourth transistor and another terminal of said second resonator; and
a fourth resonator with one terminal thereof connected to said drain of said fourth transistor, said gate of said first transistor and another terminal of said third resonator, wherein said resonators are thus arranged to form a ring. Further comprising

3. A high-frequency ring coupled Quad according to claim 2, further comprising one terminal of an input voltage (Vdd) of a voltage controlled oscillator is connected to a ground, and another terminal of said input voltage (Vdd) of said voltage controlled oscillator is connected to said first resonator, said second resonator, said third resonator and said fourth resonator in parallel.

4. A high-frequency ring coupled Quad according to claim 3, wherein said voltage controlled oscillator is fabricated with a CMOS (Complementary Metal Oxide Semiconductor) process.

5. A high-frequency ring coupled Quad according to claim 4, wherein said CMOS process is a 90 nm CMOS process.

6. A high-frequency ring coupled Quad according to claim 3, wherein said voltage controlled oscillator has a turning range of 2.5 GHz.
